(19) United States
(12) Patent Application Publication
(10) Pub. No.: US 2007/0159636 A1
(43) Pub. Date: Jul. 12, 2007

(54) Fabry-perot semiconductor tunable laser

(76) Inventor: Vijaysekhar Jayaraman, Goleta, CA (US)

Correspondence Address: Vijaysekhar Jayaraman;Praevium Research Inc., 270 Coronado Drive, Goleta, CA, 93117, US

(21) Appl. No.: 11/652,156

(22) Filed: Jan. 11, 2007

Related U.S. Application Data
(60) Provisional application No. 60/758,574, filed on Jan. 12, 2006.

(51) Int. Cl. H01S 5/00; G01J 3/45

(52) U.S. Cl. 356/451; 372/50.121; 372/50.122

(57) ABSTRACT

A tunable laser according to the present invention includes a plurality of Fabry-Perot semiconductor lasers comprising a plurality of semiconductor gain medium compositions disposed on a common sub-carrier with means for thermal tuning, and coupled to a sample. In a preferred embodiment, the lasers are coupled to a common multi-mode optical fiber, and an output radiation from the multi-mode fiber is tunable by switching the drive current amongst the lasers, and by thermal tuning of each laser in the array. In one preferred embodiment of this invention the plurality of Fabry-Perot semiconductor lasers are arranged around the perimeter of a cylindrical submount with a substantially circular cross-section. In another preferred embodiment a linear array of Fabry-Perot edge-emitting lasers is directly coupled to a multi-mode fiber. In still another preferred embodiment, an array of Fabry-Perot lasers is coupled to a fiber bundle.

### CROSS-REFERENCES TO RELATED APPLICATIONS

This application is entitled to the benefit of Provisional Patent Application Ser. No. 60/758,574, filed 2006, January 12.

### STATEMENT REGARDING FEDERALLY SPONSORED RESEARCH OR DEVELOPMENT

This invention was made under a government grant. The U.S. government may have rights in this invention.

### BACKGROUND

1. Field of the Invention

This invention relates generally to tunable sources, spectroscopy, and multi-wavelength laser arrays.

2. Description of Prior Art

Spectroscopy refers to the use of multi-wavelength radiation to non-invasively probe a variety of samples to determine the composition, health, or function of those samples. Prior-art spectroscopy is done with filtered white light sources, as illustrated in the prior art FIG. 1. Here, a white light source 100 emits a broadband radiation 130, which is filtered with a tunable monochromator 110, comprising a rotating grating 114 and slit 118, to generate a narrowband radiation 150, which probes a sample 120. A diffuse reflected radiation 160 is then detected by an optical detector 140. By tuning the monochromator 110, it is possible to construct a spectrum of the reflected radiation 160, which provides non-invasive information about the sample 120.

Although it enables spectral measurements over a wide wavelength range, the prior-art white light spectrometer of FIG. 1 suffers from a number of limitations. First, the filtered white light source has weak signal to noise ratio. Second, the grating-based system has critical intra-system mechanical alignments, and contains moving parts, leading to a bulky and complex system with slow measurement times. Lastly, some applications, such as (B. Tromberg, N. Shah, R. Lanning, A. Cerussi, J. Espinoza, T. Pham, L. Svaasand, and J. Butler, “Non-Invasive In Vivo Characterization of Breast Tumors Using Photon Migration Spectroscopy,” Neoplasia, vol. 2, nos. 1-2, January-April 2000, pp. 26-40) employ frequency domain measurements, which are not presently possible with white light sources, since white light sources cannot be easily modulated at the required 100 Mhz to 3 Ghz rates.

One solution to these problems is to replace the white-light source with a tunable laser. This eliminates the rotating grating 114, since the laser provides a source of tunable narrow-band radiation which requires no further filtering. However, prior art tunable semiconductor lasers, such as those described in (B. Mason, S. Lee, M. E. Heimbuch, and L. A. Coldren, “Directly Modulated Sampled Grating DBR Lasers for Long-Haul WDM Communication Systems,” IEEE Photonics Technology Letters, vol. 9, no. 5, March 1997, pp. 377-379), are limited in tuning range to less than 100 nanometers (nm), because of the fundamental gain-bandwidth limit of semiconductors. Most spectroscopic applications, such as near infrared spectroscopy from 1100-2400 nm, agricultural spectroscopy from 700-1700 nm, or tissue spectroscopy from 650-1000 nm, require several hundred nm bandwidth. Additionally, prior art tunable semiconductor lasers designed for telecommunications employ means to achieve extremely narrow linewidths well below 0.1 nm, which increases the cost and complexity of the device. Many spectroscopic applications can be served with linewidths in the range of 1-10 nm.

Other prior art researchers, such as those in (B. Tromberg, N. Shah, R. Lanning, A. Cerussi, J. Espinoza, T. Pham, L. Svaasand, and J. Butler, “Non-Invasive In Vivo Characterization of Breast Tumors Using Photon Migration Spectroscopy,” Neoplasia, vol. 2, nos. 1-2, January-April 2000, pp. 26-40), have assembled multiple discrete lasers to access wavelengths outside the gain bandwidth limitation of a single semiconductor laser. Such an approach employing separately packaged lasers, however, introduces complexity and cost while suffering from sparse and insufficient wavelength coverage.

From the foregoing, it is clear that what is required is a compact tunable laser with wide tuning range, substantial wavelength coverage within the range, and linewidth appropriate for spectroscopic applications, without the unnecessary complexity, cost, and size associated with narrow telecommunication linewidth lasers or multiple individually packaged lasers.

### SUMMARY OF THE INVENTION

The present invention provides a plurality of Fabry-Perot semiconductor lasers comprising a plurality of semiconductor gain medium compositions disposed on a common sub-carrier. This plurality of lasers, when operated in conjunction with thermal tuning, is operative to emit radiation over a range appropriate for many spectroscopic applications. The Fabry-Perot semiconductor lasers can be arranged on a common sub-carrier in a linear array or two-dimensional array. An output radiation from the plurality of lasers is directed to a sample either by direct coupling, through the use of one or more optical fibers, or through a waveguide photonic integrated circuit. An optical detector detects a diffuse reflectance or transmittance.

A further understanding of the nature and advantages of the present invention may be realized by reference to the remaining portions of the specifications and drawings.

### BRIEF DESCRIPTION OF THE DRAWINGS

FIG. 1 is a schematic representation of a prior art grating-based spectrometer.

FIG. 2 is a schematic representation of an end view of a preferred embodiment of the present invention.

FIG. 3 is a schematic representation of a cross-section A-A′ through a portion of FIG. 2.

FIG. 4 is a schematic representation of an experimental configuration used to test a linear 4-channel array coupled to a single large-core multi-mode fiber according to the present invention.

FIG. 5 is a spectrum of wavelength bands emitted by the 4-channel array of FIG. 4.

FIG. 6 is a schematic representation of a linear 4-channel array of Fabry-Perot semiconductor lasers coupled to a fiber bundle.

### REFERENCE NUMERALS IN DRAWINGS

100 White light source
110 Tunable monochromator
120 Sample in prior art spectrometer
130 Broadband radiation emitted by white light source
140 Optical detector in prior art spectrometer
150 Narrow band radiation in prior art spectrometer
160 Diffuse reflectance from sample in prior art spectrometer
200 Edge-emitting lasers in tunable laser according to present invention
210 Multi-mode fiber core in tunable laser according present invention
220 Cylindrical submount in tunable laser according to present invention
250 Flex circuit in tunable laser according to present invention
260 Circuit board in tunable laser according to present invention
270 Radiation components from edge-emitting lasers in tunable laser according to present invention
280 Electrical connections in tunable laser according to present invention
290 Optical axis of cylindrical submount in tunable laser according to present invention
300 Radiation output from fiber core in tunable laser according to present invention
310 Sample in tunable laser according to present invention
320 Reflectance from sample in tunable laser according to present invention
330 Optical detector in tunable laser according to present invention
340 Thermo-electric cooler in tunable laser according to present invention
350 Mode diffuser sheet in tunable laser according to present invention
400 4-channel linear array in tunable laser according to present invention
410 positive probe
420 negative probe
430 Temperature-controlled stage
440 Plurality of radiation components from 4-channel linear array
450 1 mm core diameter fiber used to test 4-channel linear array
460 Fiber bundle in tunable laser according to present invention
500 First wavelength band
510 Second wavelength band
520 Third wavelength band
530 Fourth wavelength band

### DETAILED DESCRIPTION OF THE PREFERRED EMBODIMENTS

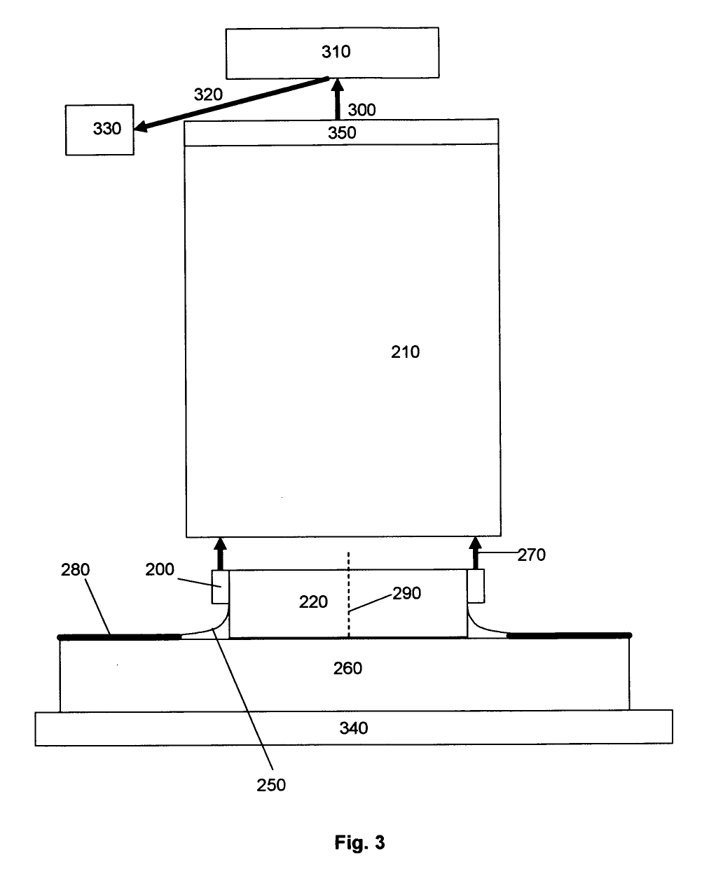

FIGS. 2 and 3 represent two views of a preferred embodiment of the present invention. FIG. 2 is an end view of a preferred embodiment of the present invention. The view of FIG. 2 is looking from the inside of a multi-mode optical fiber core 210 at a plurality of edge-emitting Fabry-Perot semiconductor lasers 200 arranged around the perimeter of a circular cross-section sub-carrier 220, fitting within the core of the multi-mode optical fiber 210. Throughout this specification, whenever the term sub-carrier is used, it is assumed to mean either a semiconductor substrate, in the case of monolithic integration of multiple lasers, or simply a common mount in the case of multiple Fabry-Perot laser die. The optical fiber 210 could also be replaced by a lightpipe, such as a glass rod, in some applications. Each of the plurality of lasers 200 employs a unique semiconductor gain medium composition with a unique gain peak wavelength. For example, the gain media could be quantum well regions with various compositions of InGaAsP, having gain peak wavelengths in the 1200-2100 nm range. The gain regions can be composed of any semiconductor known to provide optical gain for laser radiation. The use of a plurality of gain medium compositions overcomes the gain-bandwidth limitations of a single semiconductor gain medium, and enables the wide wavelength coverage required for spectroscopic applications. The use of Fabry-Perot lasers instead of single-mode lasers such as DFB/DBR lasers leads to an inexpensive and easily manufactured device, which retains a spectral resolution of 1-5 nm, which is adequate for many spectroscopic applications.

The plurality of Fabry-Perot semiconductor lasers 200 emits a plurality of radiation components 270 having a plurality of wavelengths into the fiber core 210 directly with no intervening optics. That is, the semiconductor lasers 200 are directly coupled to the optical fiber core 210. Throughout this specification, the phrase “directly coupled” refers to coupling with no intervening optical components. The numerical aperture of the fiber with core 210 is preferably in the range of about 0.35 to about 0.5, enabling >50% coupling efficiency of edge-emitting semiconductor lasers with direct coupling. FIG. 2 shows typical dimensions of this arrangement, wherein each edge-emitting semiconductor laser has a width around 250 microns and a thickness around 75 microns, enabling 14 such sources to be placed around the perimeter of the 1.15 mm diameter sub-carrier 220. This enables the plurality of radiation components 270 to fit within the 1.5 mm diameter fiber core 210. Typical fiber core or lightpipe diameters for multi-mode sensor applications are in the range of about 50 microns to about 5 millimeters.

FIG. 3 is a view of the section A-A′ indicated in FIG. 2, illustrating how the Fabry-Perot semiconductor lasers 200 can be connected to a circuit board 260, which in turn is connected to an external power supply through electrical connections 280. The circuit board 260 rests on a thermo-electric cooler 340. The connection between sources 200 and the circuit board 260 requires a 90 degree electrical bend, accomplished by a flex circuit 250, which is well-known to those skilled in the art. The electrical signals traveling along the connections 280 are in a plane substantially perpendicular to an axis 290 of the cylindrical sub-carrier 220. FIG. 3 also shows how an output radiation 300 from the fiber core 210 impinges on a sample 310, generating a diffusely reflected radiation 320 detected by a broadband optical detector 330. Broadband optical detectors include, but are not limited to Indium Gallium Arsenide p-i-n detectors, silicon p-i-n detectors, and silicon avalanche photodiode detectors. The most appropriate broadband detector for a particular application depends on the wavelength range and signal to noise ratio required, as is well-known to those skilled in the art.

FIG. 3 also illustrates a mode diffuser sheet 350 interposed between the fiber 210 and the sample 310. This mode diffuser sheet is commercially available and serves to mix the various modes of the optical fiber, and increase the spatial homogeneity of the radiation 300. Spatial homogeneity is important for some applications and not for others, and the mode diffuser sheet 350 can be eliminated in some cases. Mode mixing for spatial homogeneity can also be accomplished by other means well-known to those skilled in the art, such as increasing the length of the fiber 210, or introducing mechanical stresses into the fiber 210. The mode diffuser sheet 350, however, is the preferred embodiment.

The components of FIGS. 2 and 3 function together as key elements of a compact semiconductor laser-based spectrometer. By sequentially switching a power supply external to the circuit board 260, amongst the electrical connections 280 to the lasers 200, only one of the lasers is emitting radiation at any given time, and selecting the laser selects the wavelength. Wavelength sweeping can be accomplished by sequentially powering each of the lasers 200. In an alternate but not preferred embodiment, all of the lasers can be operated simultaneously and modulated at slightly different modulation frequencies. The reflectivity at each wavelength is then extracted by filtering at each modulation frequency.

Further wavelength tuning can be achieved by temperature control of the sub-carrier 220, using the thermo-electric cooler 340, or by resistive heaters integrated with each laser 200, or by a combination of both. A resistive heater could also be integrated with the sub-carrier 220. The thermal tuning rate of lasing wavelength for the Fabry-Perot lasers 200 is equal to the thermal tuning rate of the gain peak, which is in the range of about 0.4 nm/C around 980 nm. This thermal tuning rate is much greater than the thermal tuning rate of grating based lasers such as DFB/DBR lasers, which tune at about 0.08 nm/C around 980 nm, or at a rate proportional to the thermal tuning rate of the material index of refraction.

For example, in the 650-1000 nm range, approximately 12 Fabry-Perot semiconductor lasers arranged around the perimeter of a nearly circular cross-section polygon can, in conjunction with thermal tuning, provide complete wavelength coverage of the 650-1000 nm range. An important application of this wavelength range is in broadband diffuse optical spectroscopy for detection of water, lipids, oxy-hemoglobin, and deoxy-hemoglobin, in the detection, characterization, and therapeutic monitoring of breast cancer. This application is one example of an in-vivo biological measurement, and is discussed in (B. Tromberg, N. Shah, R. Lanning, A. Cerussi, J. Espinoza, T. Pham, L. Svaasand, and J. Butler, “Non-Invasive In Vivo Characterization of Breast Tumors Using Photon Migration Spectroscopy,” Neoplasia, vol. 2, nos. 1-2, January-April 2000, pp. 26-40). This application requires both steady state and frequency domain measurements of diffuse tissue reflectance, and the embodiment of FIGS. 2 and 3 addresses this need. Frequency domain measurements can be accomplished by applying a modulated drive current to one or more of the lasers 200. This modulation range is typically in the range of about 100 Mhz to about 3 Ghz. The embodiment of FIGS. 2 and 3 could also be used to characterize biological samples ex vivo. For this and many other applications, the spectral width of Fabry-Perot lasers, which is on the order of 1-5 nm, is adequately narrow to enable high sensitivity detection, and the <0.1 nm linewidth of grating-based semiconductor lasers such as DFB/DBR lasers is not required.

Although the configuration of FIGS. 2 and 3 employs a circular cross-section cylinder, it is evident that the cross-section can be a polygon of any shape, such as a square, or a many-sided polygon with 4-16 facets. (Throughout this specification, we assume that the term polygon includes circles.) This is especially true when uniform modal excitation is not critical, as is the case of broadband diffuse optical spectroscopy in the 650-1000 nm range.

Although the preferred embodiment of FIGS. 2 and 3 employs an optical fiber to direct radiation to the sample, some applications do not require an optical fiber, and the lasers 200 can be directly coupled to the sample to be measured. An example of such an application is (B. Tromberg, N. Shah, R. Lanning, A. Cerussi, J. Espinoza, T. Pham, L. Svaasand, and J. Butler, “Non-Invasive In Vivo Characterization of Breast Tumors Using Photon Migration Spectroscopy,” Neoplasia, vol. 2, nos. 1-2, January-April 2000, pp. 26-40). Here, the source detector separation is on the order of 1 cm, and the maximum allowed illumination region traverses 1-3 mm. Spatial non-uniformity of the source intensity over the maximum allowed illumination region is relatively un-important. Thus, as long as the sources 200 are clustered over a spatial extent smaller than the maximum allowed illumination region, the sources can be directly coupled to in-vivo tissue.

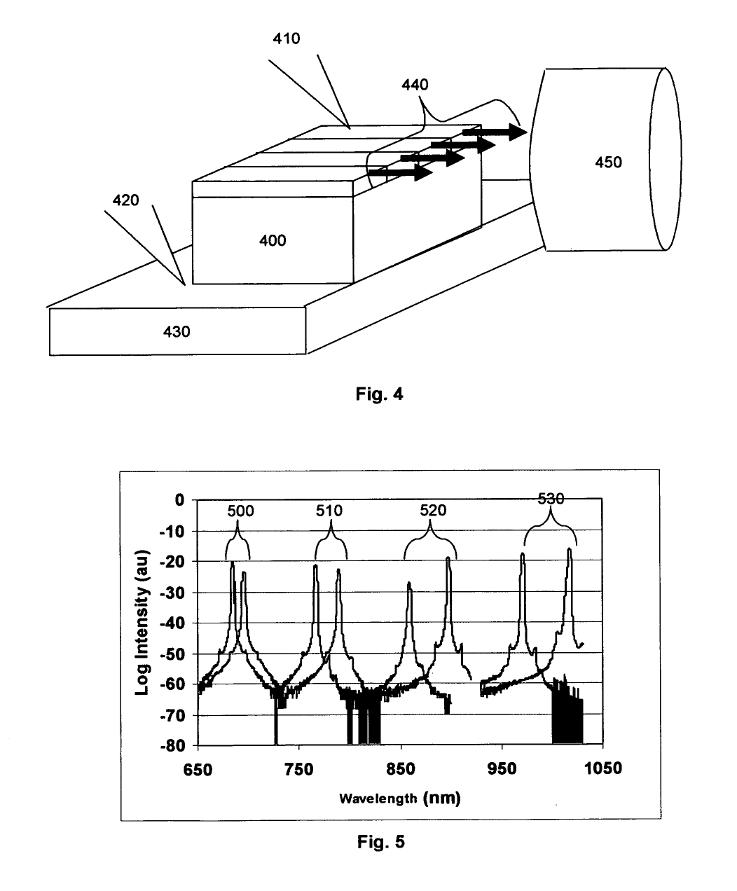

Another preferred embodiment of this invention, when the number of wavelengths is small, is a linear array. For example, in a 4-channel system, a linear array of four edge-emitting lasers with a width of 250 microns each can fit within the 1 mm core of a multi-mode fiber. Linear arrays can also be stacked to make two-dimensional arrays which can be directly coupled to fiber. FIG. 4 shows a preferred linear array embodiment, along with an experimental configuration used to test a prototype 4-channel array. In this experiment, a four element edge-emitting laser array 400, having an element to element spacing of 250 microns was fabricated and tested. A first element of this array employed an AlInGaP quantum well gain region emitting around 680 nm, a second element employed an AlGaAs quantum well gain region emitting around 780 nm, a third element employed a GaAs quantum well gain region emitting around 880 nm, and a fourth element employed an InGaAs quantum well gain region emitting around 980 nm. The array 400 was assembled from four individually processed laser die using a manual pick and place tool. Linear arrays employing a plurality of gain regions could also be assembled monolithically on a wafer scale, using wafer bonding techniques such as that described in (J. Geske, D. Leonard, M. H. MacDougal, B. Barnes, and J. E. Bowers, “CWDM Vertical Cavity Surface-Emitting Laser Array Spanning 140 nm of the C, S, and L Fiber Transmission Bands,” IEEE Photonics Technology Letters, vol. 16, no. 5, May 2004). As described earlier, in the case of monolithic integration, the semiconductor substrate functions as the subcarrier. Current was applied to each element of the array 400 through a positive electrode 410 and a negative electrode 420. The array emitted four radiation components 440 having four wavelength bands into a common multi-mode fiber 450 having a core diameter of 1 mm. The fiber was held in a fixed position as the array elements were probed sequentially, and the spectrum from each element of the array was measured during thermal tuning. FIG. 5 illustrates the spectra observed from the four channels at the fiber output. The four elements of the array emit radiation in first, second, third and fourth wavelength bands 500, 510, 520, and 530, respectively, in the 650-1000 nm wavelength range, representing a total wavelength coverage of about 120 nm. FIGS. 4 and 5 represent reduction to practice of the present invention for the specific case of a linear array of four lasers directly coupled to one common multi-mode fiber, in the 650-1000 nm wavelength range. The thermal tuning demonstrated by the four channel array in FIGS. 4 and 5 suggests the feasibility of complete wavelength coverage from 650-1000 nm using 12 thermally tuned Fabry-Perot semiconductor lasers.

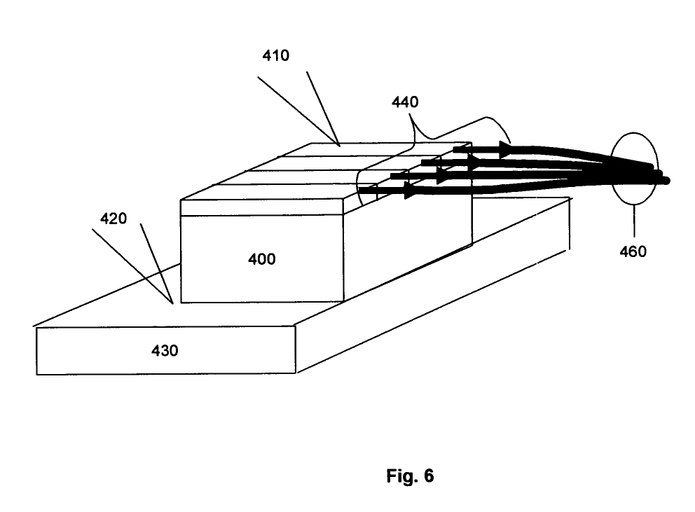

FIG. 6 illustrates an alternate embodiment of the present invention. Here the linear array 400 of FIG. 4 is coupled not to a single optical fiber 450, but to a fiber bundle 460. The embodiment of FIG. 6 may be employed in place of the single fiber 450 in cases where a small bend radius is required to direct the radiation components 440 to a desired sample. It can also be employed when spatial extent occupied by the sources is larger than the maximum allowed illumination area of the sample. In an alternate embodiment, the fiber bundle 460 can be replaced by an array of passive waveguides in a passive photonic integrated circuit, for cases where the source extent is larger than the allowed illumination area. The passive photonic integrated circuit brings source radiation components closer together before impinging on the sample.

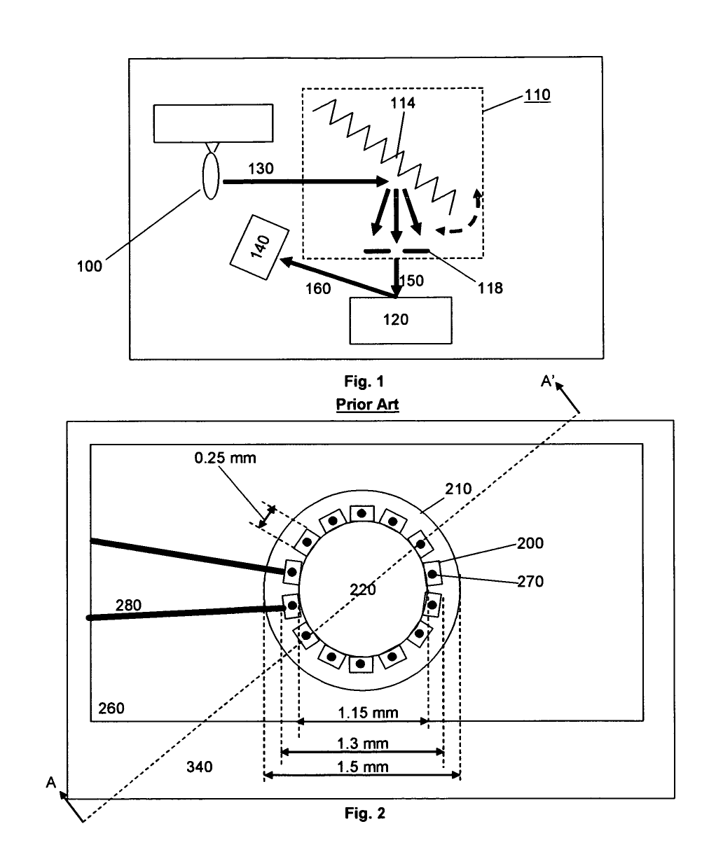

In addition to the 650-1000 nm wavelength range, other ranges and applications of interest for all embodiments of the present invention include the 700-1700 nm range for agricultural applications, and the 1100-2500 nm range for near-infrared spectroscopy. The 700-1700 nm range has proved useful in the spectroscopy of wheat, corn, and insects. See, for example (F. E Dowell, T. C. Pearson, E. B. Maghirang, F. Xie, and D. T. Wicklow, “Reflectance and Transmittance Spectroscopy Applied to Detecting Fumonism in Single Corn Kernels Infected with Fusarium Verticillioides,” Cereal Chemistry vol. 79 (2), pp. 222-226, 2002). The 1100-2500 nm range is extensively used in the characterization of pharmaceutical products, and is a standard wavelength range for near infrared spectroscopy. Both of the above applications rely extensively on prior art grating-based spectrometers such as those of FIG. 1, or variants thereof. The present invention promises more compact instrumentation, greater signal to noise ratio, lower power dissipation, and faster measurement times. In addition, the entire wavelength range from about 650 nm to about 2500 nm can be accessed with relatively mature semiconductor laser technology, making the approach feasible. The above application areas are only intended as examples, and are not intended to be limiting. The present invention can be applied wherever spectroscopy provides useful information, using edge-emitting Fabry-Perot semiconductor lasers of any available wavelength.

While this invention has been particularly shown and described with references to preferred and alternate embodiments thereof, it will be understood by those skilled in the art that various changes in form and details may be made therein without departing from the spirit and scope of the invention as defined by the appended claims.

What is claimed is:

1. A tunable radiation source comprising,
a plurality of Fabry-Perot semiconductor lasers comprising a plurality of semiconductor gain medium compositions, operative to emit a plurality of radiation components having a plurality of wavelengths, said plurality of Fabry-Perot semiconductor lasers assembled on a common sub-carrier,
a first means for thermal tuning of at least one of said plurality of Fabry-Perot semiconductor lasers, thereby tuning at least one of said plurality of wavelengths,
a second means for directing said plurality of radiation components to a sample and
a third means for powering each one of said plurality of semiconductor lasers.

2. The tunable radiation source of claim 1, wherein said plurality of Fabry-Perot semiconductor lasers encompasses between about 4 and about 16 Fabry-Perot semiconductor lasers.

3. The tunable radiation source of claim 1, wherein said plurality of Fabry-Perot semiconductor lasers is arranged in a linear array.

4. The tunable radiation source of claim 1, wherein said plurality of Fabry-Perot semiconductor lasers is arranged in a 2-dimensional array.

5. The tunable radiation source of claim 1, wherein said second means comprises coupling said plurality of radiation components to a single multi-mode optical fiber.

6. The tunable radiation source of claim 5, further comprising a fourth means for increasing a spatial homogeneity of a radiation pattern at an output of said multi-mode optical fiber.

7. The tunable radiation source of claim 6, wherein said fourth means comprises a mode diffuser sheet.

8. The tunable radiation source of claim 6, wherein said fourth means comprises propagation along a length of optical fiber.

9. The tunable radiation source of claim 6, wherein said fourth means comprises introducing mechanical stress into said multi-mode optical fiber.

10. The tunable radiation source of claim 1, wherein said second means comprises coupling said plurality of radiation components to a fiber bundle.

11. The tunable radiation source of claim 1, wherein said second means comprises coupling said plurality of radiation components to a passive photonic integrated circuit.

12. The tunable radiation source of claim 1, wherein said second means comprises direct coupling of said plurality of radiation components to a sample.

13. The tunable radiation source of claim 1, wherein said plurality of wavelengths is in a range between about 650 nm and about 1000 nm.

14. The tunable radiation source of claim 1, wherein said plurality of wavelengths is in a range between about 1100 nm and about 2500 nm.

15. The tunable radiation source of claim 1, wherein said plurality of wavelengths is in a range between about 700 nm and about 1700 nm.

16. The tunable radiation source of claim 1, wherein said plurality of wavelengths encompasses substantially complete wavelength coverage over a range between about 650 nm and about 1000 nm.

17. The tunable radiation source of claim 1, wherein said plurality of wavelengths encompasses substantially complete wavelength coverage over a range between about 1100 nm and about 2500 nm.

18. The tunable radiation source of claim 1, wherein said plurality of wavelengths encompasses substantially complete wavelength coverage over a range between about 700 nm and about 1700 nm.

19. The tunable radiation source of claim 1, further comprising means for electrically modulating at least one of said plurality of Fabry-Perot semiconductor lasers at frequencies in a range of about 100 Mhz to about 3 Ghz.

20. The tunable radiation source of claim 4, wherein said plurality of Fabry-Perot semiconductor lasers is arranged around the perimeter of a cylindrical sub-carrier, wherein a cross-section of said cylindrical sub-carrier is a polygon.

21. The tunable radiation source of claim 20, wherein said polygon has between about 4 and about 16 sides.

22. The tunable radiation source of claim 20, wherein said polygon is a circle.

23. The tunable radiation source of claim 20, further comprising a means for bending a path of said electrical power into a plane substantially perpendicular to an axis of said cylindrical sub-carrier.

24. The tunable radiation source of claim 23, wherein said means for bending a path of said electrical power is a flex circuit.

25. A spectrometer comprising the tunable source of claim 1, and further comprising a fifth means for detecting at least one of a radiation reflected from said sample and a radiation transmitted through said sample.

26. The spectrometer of claim 25, wherein said sample is an in-vivo biological sample.

27. The spectrometer of claim 25, wherein said sample is an ex-vivo biological sample.

28. The spectrometer of claim 25, wherein said sample is an agricultural sample.

29. The spectrometer of claim 25, wherein said sample is a corn kernel.

30. The spectrometer of claim 25, wherein said sample is a wheat kernel.

31. The spectrometer of claim 25, wherein said sample is a pharmaceutical sample.

32. A system for at least one of the detection, characterization, and therapeutic monitoring of breast cancer, the system comprising the spectrometer of claim 25, wherein said sample is in-vivo human breast tissue.

33. A system for at least one of the detection, characterization, and therapeutic monitoring of breast cancer, the system comprising the spectrometer of claim 25, wherein said sample is in-vivo human breast tissue, and further comprising means for modulating at least one of said plurality of Fabry-Perot semiconductor lasers at frequencies in a range of about 100 Mhz to about 3 Ghz.

34. The system of claim 32, wherein said plurality of wavelengths is in the range of about 650 nm to about 1000 nm.

35. The system of claim 33, wherein said plurality of wavelengths is in the range of about 650 nm to about 1000 nm.

36. The tunable source of claim 1, wherein said first means comprises a thermo-electric cooler.

37. The tunable source of claim 1, wherein said first means comprises at least one integrated resistive heater.

38. The tunable source of claim 37, wherein said at least one integrated resistive heater is monolithically integrated with at least one of said plurality of Fabry-Perot semiconductor lasers.
